(19) United States
(12) Patent Application Publication
(10) Pub. No.: US 2025/0275401 A1
(43) Pub. Date: Aug. 28, 2025

(54) DISPLAY APPARATUS

(71) Applicant: LG Display Co., Ltd., Seoul (KR)

(72) Inventor: Changyung PARK, Seoul (KR)

(73) Assignee: LG Display Co., Ltd., Seoul (KR)

(21) Appl. No.: 19/062,863

(22) Filed: Feb. 25, 2025

(30) Foreign Application Priority Data
Feb. 26, 2024 (KR) 10-2024-0027344

(51) Int. Cl. H10K 59/131; H10K 102/00

(52) U.S. Cl. CPC H10K 59/131; H10K 2102/351

(57) ABSTRACT

A display apparatus is capable of delaying or preventing the disconnection of signal lines in a bending area of a substrate. The display apparatus can include the substrate and at least one signal line. The substrate can include a display area having a plurality of sub-pixels and a non-display area adjacent to the display area and having the bending area. The signal line can be disposed in the bending area on the substrate. The signal line can include at least one first layer, a second layer surrounding an upper surface, side surfaces, and a lower surface of the first layer, and a third layer surrounding an upper surface, side surfaces, and a lower surface of the second layer.

### CROSS-REFERENCE TO RELATED APPLICATION

The present application claims priority to Korean Patent Application No. 10-2024-0027344, filed Feb. 26, 2024, the entire contents of which is hereby expressly incorporated by reference into the present application.

### BACKGROUND

### Field

The present disclosure relates to a display apparatus.

### Discussion of the Related Art

In line with the information age, various display apparatuses are being developed. Examples of such flat panel display apparatuses include liquid crystal display apparatuses (LCDs), organic light emitting display apparatuses (OLEDs), micro light emitting diode (LED) display apparatuses, and quantum dot (QD) display apparatuses, etc.

As the display apparatuses are used in various ways, various designs are being made to reduce an area of a non-display area that is visible to users to provide the users with a sense of immersion and aesthetics.

The description provided in the background section should not be assumed to be prior art merely because it is mentioned in or associated with the background section. The background section can include information that describes one or more aspects of the subject technology.

### SUMMARY OF THE DISCLOSURE

Recently, display apparatuses using a flexible substrate have been developed, and there have been attempts to reduce an area of a non-display area by folding or bending at least a portion of the non-display area of the flexible substrate and positioning the portion under a display area in which an image is displayed.

Stress applied to the folded or bent area, for example, the bending area of the flexible substrate can cause micro cracks in signal lines positioned in the bending area.

Therefore, the inventor of the present disclosure has invented a new structure of lines that can delay or prevent cracking and disconnection of signal lines of a flexible substrate.

Embodiments of the present disclosure are directed to providing a display apparatus that is capable of delaying or preventing disconnection of signal lines disposed in a bending area of a flexible substrate.

The objects of the present disclosure are not limited to the above-described objects, and other objects that are not mentioned will be able to be clearly understood by those skilled in the art from the following description.

A display apparatus according to embodiments of the present disclosures includes a substrate including a display area having a plurality of sub-pixels and a non-display area surrounding the display area and having a bending area, and at least one signal line disposed in the bending area on the substrate, wherein the at least one signal line includes at least one first layer, a second layer surrounding an upper surface, side surfaces, and lower surface of the at least one first layer, and a third layer surrounding an upper surface, side surfaces, and lower surface of the second layer.

A display apparatus according to embodiments of the present disclosure includes a substrate including a display area having a plurality of sub-pixels and a non-display area disposed near the display area, and at least one signal line disposed in the non-display area on the substrate, wherein the at least one signal line can include at least one core layer, a first shell layer surrounding an upper surface, side surfaces, and lower surface of the at least one core layer, and a second shell layer surrounding an upper surface, side surfaces, and lower surface of the first shell layer.

Detailed matters of other embodiments of the present disclosure are included in a detailed description and accompanying drawings.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view showing a display apparatus according to a first embodiment of the present disclosure.

FIG. 2 is a plan view showing the display apparatus according to the first embodiment of the present disclosure.

FIG. 3 is a cross-sectional view along line 3-3 in FIG. 2.

FIG. 4 is a cross-sectional view along line 4-4 in FIG. 2.

FIG. 5 shows a corrosion process of a signal line according to the first embodiment of the present disclosure.

FIG. 6 is a cross-sectional view according to a second embodiment of the present disclosure.

FIG. 7 is a cross-sectional view according to a third embodiment of the present disclosure.

FIG. 8 shows a corrosion process of a signal line according to the third embodiment example of the present disclosure.

FIGS. 9A to 9D show a manufacturing method of a signal line according to the first embodiment of the present disclosure.

FIGS. 10A to 10D show a manufacturing method of a signal line according to the first embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the disclosure and can be thus different from those used in actual products.

Advantages and features of the present disclosure and methods for achieving them will become clear with reference to embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes (e.g., sizes, lengths, widths, heights, thicknesses, locations, radii, diameters, and areas), ratios, angles, numbers, and the like disclosed in the drawings for describing the embodiments of the present disclosure are illustrative, the present disclosure is not limited to the illustrated items. The same reference number denotes the same components throughout the disclosure. In addition, in describing the present disclosure, when it is determined that the detailed description of a related known technology can unnecessarily obscure the gist of the present disclosure, detailed description thereof will be omitted. When terms “comprises,” “has,” “include,” “consists of,” and the like described in the present disclosure are used, other parts can be added unless “only” is used. When a component is expressed in the singular, it includes a case in which the component is provided as a plurality of components unless specifically stated otherwise.

The word “exemplary” is used to mean serving as an example or illustration. Aspects are example aspects. Further, “embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “may.”

In construing a component, the component is construed as including the margin of error even when there is no separate explicit description.

When the positional relationship is described, for example, when the positional relationship between two parts is described using the term “on,” “over,” “above,” “under,” “next to,” or the like, one or more other parts can be positioned between the two parts unless the term “immediately” or “directly” is used.

The terms, such as “below,” “lower,” “above,” “upper” and the like, can be used herein to describe a relationship between element(s) as illustrated in the drawings. It will be understood that the terms are spatially relative and based on the orientation depicted in the drawings.

Although terms such as first and second “A,” “B,” “(a),” and “(b),” are used to describe various components, the components are not limited by the terms. The terms are only used to distinguish one component from another, and may not define order or sequence. Therefore, a first component described below can be a second component within the technical spirit of the present disclosure.

The same reference number denotes the same components throughout the disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

The size and thickness of each component shown in the drawings are shown for convenience of description, and the present disclosure is not necessarily limited to the sizes and thicknesses of the components shown.

Features of various embodiments of the present disclosure can be partially or fully coupled or combined, and as can be fully understood by those skilled in the art, various technical interconnection and operations are possible, and the embodiments can be implemented independently of each other and implemented together in combination thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, display apparatuses according to various embodiments of the present disclosure will be described in detail with reference to the accompanying drawings. All the components of each display apparatus according to all embodiments of the present disclosure are operatively coupled and configured.

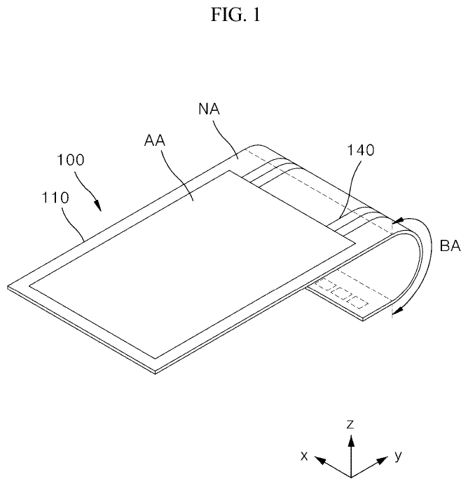

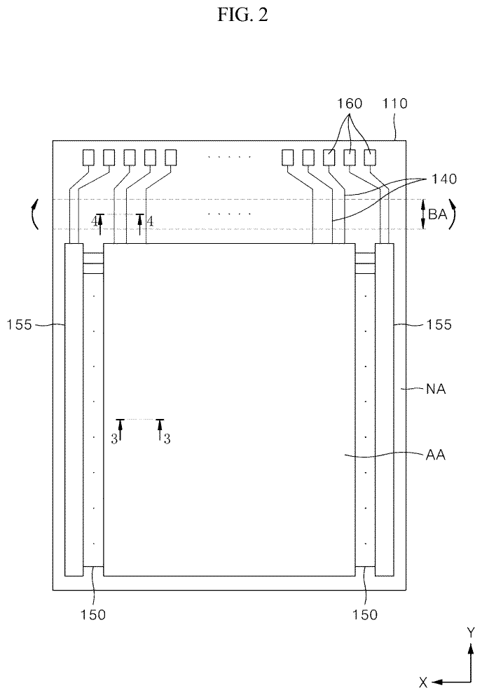

FIG. 1 is a perspective view showing a display apparatus according to a first embodiment of the present disclosure. FIG. 2 is a plan view showing the display apparatus according to the first embodiment of the present disclosure.

Particularly, FIG. 1 shows a state in which a portion of a substrate 110 of a display apparatus 100 has been folded or bent, and FIG. 2 shows a state in which the substrate 110 of the display apparatus 100 has been unfolded as an example for convenience of description.

Referring to FIGS. 1 and 2, the display apparatus 100 according to the first embodiment of the present disclosure can include a display area AA (or active area) and a non-display area NA (or non-active area) disposed near the display area AA on the substrate 110. The substrate 110 can be a flexible substrate. A bending area BA, which is an area in which a portion of the flexible substrate can have a curvature due to folding or bending, can be present in the non-display area NA. As an example, the non-display area NA can extend from the display area AA. As an example, the non-display area NA can fully or partially surround the display area AA. As an example, the bending area BA can be disposed to be adjacent to the display area AA or to be spaced apart from the display area AA. Although it is illustrated that there is one bending area BA in the non-display area NA, embodiments are not limited thereto. As an example, there could be two or more bending areas in the non-display area NA. As an example, the two or more bending areas can be disposed in the same direction or different directions (e.g., opposite directions, without being limited thereto) with respect to the display area AA.

The display area AA of the substrate 110 is an area in which a plurality of sub-pixels are disposed to display an image. Each of the plurality of sub-pixels is an individual unit that emits light, and each sub-pixel can emit, for example, light of red, green, blue, or white, but is not limited thereto. A light emitting element for displaying an image and/or a circuit unit for driving the light emitting element can be disposed in each of the plurality of sub-pixels of the display area AA. The circuit unit can include at least one thin film transistor and at least one capacitor. The light emitting element can be, for example, an organic light emitting diode, a light emitting diode, a Micro-LED, without being limited thereto.

The non-display area NA of the substrate 110 is an area in which an image is not displayed. As an example, the non-display area NA is an area in which a driving circuit for driving a plurality of sub-pixels disposed in the display area AA and/or various lines are disposed. For example, a driving circuit such as a gate driving circuit 155, scan lines 150, and signal lines 140 can be disposed in the non-display area NA. A data driving circuit can further be disposed in the non-display area NA. The gate driving circuit 155 can be disposed in the form of a gate driver-in-panel (GIP) on the flexible substrate 110. Embodiments are not limited thereto. As an example, the data driving circuit and/or the gate driving circuit can be separately disposed in a separate panel and connected to the substrate 110, for example, in a tape automated bonding (TAB) method, a chip on glass (COG) method, a chip on panel (COP) method, or a chip on film (COF) method, without being limited thereto. The non-display area NA can be a bezel area and is not limited to the term. As an example, at least a part of the non-display area NA can be bent or folded toward a rear side of the substrate 110 to be invisible from a front side of the substrate 110, without being limited thereto.

The non-display area NA can be an area surrounding an edge of the display area AA. Although FIGS. 1 and 2 show that the non-display area NA surrounds the rectangular display area AA, the shape of the display area AA and the shape and arrangement of the non-display area NA adjacent to the display area AA are not limited to the example shown in FIGS. 1 and 2. The display area AA and the non-display area NA can have a shape that is suitable for the design of an electronic device on which the display apparatus 100 is mounted. Example shapes of the display area AA can be pentagonal, hexagonal, circular, oval, etc. and are not limited thereto.

Pads 160 can be disposed at one side (or two or more sides) of the non-display area NA, and external modules can be coupled to the pads 160. The external modules can include, for example, a chip on film (COF) on which a data driver IC is mounted, a flexible printed circuit board (FPCB) on which a timing controller and a power management IC are mounted, etc., without being limited thereto.

The bending area BA can be a portion of the non-display area NA and provided, for example, between the display area AA and the pads 160 positioned in the non-display area NA. The bending area BA can have a curvature as the non-display area NA of the substrate 110 is bent. As an example, the bending area BA can have a curvature as the non-display area NA of the substrate 110 is bent as indicated by an arrow to arrange the pads 160 under the display area AA, without being limited thereto.

When a portion of the non-display area NA of the substrate 110 is bent under the display area AA, the size of the non-display area NA that is visible when viewed from the top of the substrate 110 can be reduced, thereby implementing a narrow bezel.

A plurality of signal lines 140 connected to the display area AA, the gate driving circuit 155, etc. can be connected to the pads 160 through the bending area BA of the non-display area NA.

The signal lines 140 disposed in the bending area BA can receive a tensile force when the substrate 101 is bent. Due to such a tensile force, micro-cracks can occur in the signal lines 140.

As an example, the signal lines 140 can be formed in a straight shape in the bending area BA. However, to reduce the tensile force applied to the signal lines 140, the signal lines 140 can be formed in various shapes, such as a triangle wave shape, a sine wave shape, an omega (Ω) shape, and a rhombus shape, in the bending area BA, without being limited thereto.

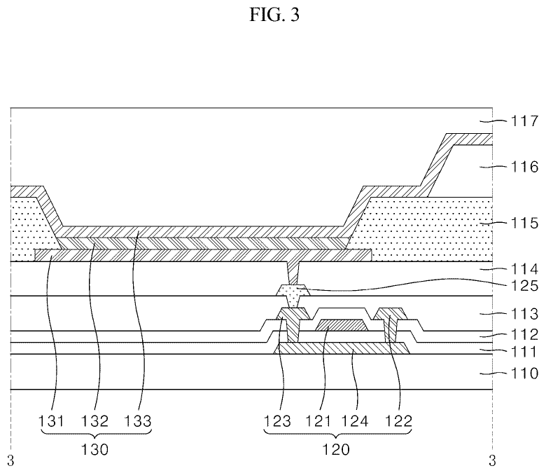

FIG. 3 is a cross-sectional view along line 3-3 in FIG. 2.

Referring to FIG. 3, the substrate 110 can serve to support and protect components of the display apparatus 100 and can be a flexible substrate made of a material having the flexible property. For example, the flexible substrate can be in the form of a film containing one selected from the group consisting of a polyester polymer, a silicone polymer, an acrylic polymer, a polyolefin polymer, and a copolymer thereof, without being limited thereto.

A buffer layer can be further disposed on the substrate 110. The buffer layer can reduce or prevent the penetration of moisture or other impurities through the substrate 110. The buffer layer can be omitted depending on the type of the substrate 110 or the type of the thin film transistor 120 disposed on the substrate 110.

The thin film transistor 120 disposed on the substrate 110 includes a gate electrode 121, a source electrode 122, a drain electrode 123, and a semiconductor layer 124.

The semiconductor layer 124 can be made of amorphous silicon, polycrystalline silicon, an oxide semiconductor, a compound semiconductor, or an organic semiconductor, but is not limited thereto.

A gate insulating layer 111 can be an insulating layer. As an example, the gate insulating layer 111 can be an insulating layer formed of a single layer or multiple layers of silicon oxide (SiOₓ) or silicon nitride (SiNₓ), without being limited thereto.

An interlayer insulating layer 112 can be disposed between the gate electrode 121 and the source electrode 122 and between the gate electrode 121 and the drain electrode 123. As an example, the interlayer insulating layer 112 can be formed of a single layer or multiple layers of silicon oxide (SiOₓ) or silicon nitride (SiNₓ), without being limited thereto.

The gate electrode 121, the source electrode 122, and the drain electrode 123 can be formed of a conductive material. As an example, the gate electrode 121, the source electrode 122, and the drain electrode 123 can be formed of a single layer or multiple layers of one of molybdenum (Mo), aluminum (Al), chromium (Cr), gold (Au), titanium (Ti), nickel (Ni), neodymium (Nd), and copper (Cu), or an alloy thereof, but is not limited thereto. As an example, the gate electrode 121, the source electrode 122, and the drain electrode 123 can be formed of the same material or different materials.

A passivation layer formed of an inorganic insulating layer such as silicon oxide (SiOₓ) or silicon nitride (SiNₓ) can be further disposed on the thin film transistor 120.

Although FIG. 3 shows the thin film transistor 120 having a coplanar structure, the display apparatus can include a thin film transistor having an inverted staggered structure.

For convenience of description, only one thin film transistor among various thin film transistors that can be included in the display apparatus is shown, but additional thin film transistors, capacitors, etc. can also be included in the display apparatus.

To protect the thin film transistor 120 and reduce a step formed by the thin film transistor 120, a first planarization layer 113 can be disposed on the thin film transistor 120.

The first planarization layer 113 can be made of an organic insulating material, without being limited thereto. An intermediate electrode 125 can be connected to the thin film transistor 120 through a contact hole formed in the first planarization layer 113.

A second planarization layer 114 covering the intermediate electrode 125 can be disposed by being stacked on the first planarization layer 113. The second planarization layer 114 can be made of an organic insulating material, without being limited thereto.

A light emitting element 130 disposed on the second planarization layer 114 can include an anode 131, a light emitting part 132, and a cathode 133. The anode 131 can be disposed on the second planarization layer 114.

The anode 131 is an electrode that serves to supply holes to the light emitting part 132, is connected to the intermediate electrode 125 through a contact hole in the second planarization layer 114, and is electrically connected to the thin film transistor 120 through the intermediate electrode 125. Embodiments are not limited thereto. As an example, the intermediate electrode 125 and/or the second planarization layer 114 can be omitted depending on the design. As an example, the anode 131 can be directly connected to the thin film transistor a contact hole in the second planarization layer 114 and/or the first planarization layer 113.

The anode 131 can contain a conductive material. As an example, the anode 131 can contain a transparent conductive material such as indium tin oxide (ITO) or indium zinc oxide (IZO), but is not limited thereto.

When the display apparatus 100 is a top emission type that emits light upward through the cathode 133, the anode 131 can further include a reflective layer so that the emitted light can be reflected from the anode 131, without being limited thereto. For example, the anode 131 can have a two-layer structure in which a transparent conductive layer made of a transparent conductive material and a reflective layer are sequentially stacked or a three-layer structure in which a transparent conductive layer, a reflective layer, and a transparent conductive layer are sequentially stacked, and the reflective layer can be silver (Ag) or an alloy containing silver. Embodiments are not limited thereto. As an example, the anode 131 can be made of a single layer or a multiple layer of any one or more conductive materials.

A bank layer 115 disposed on the anode 131 and the second planarization layer 114 can define a sub-pixel that can actually define an area in which light emits. As an example, after forming a photoresist on the anode 131, the bank layer 115 can be formed by a photolithography process, without being limited thereto. As an example, the bank layer 115 can be formed of any insulating material other than the photoresist, via any process other than the photolithography process.

To form the light emitting part 132 of the light emitting element 130, a fine metal mask, which is a deposition mask, can be used. In addition, to reduce or prevent damages of the bank layer 115 that can occur due to the contact with the deposition mask disposed on the bank layer 115 and maintain a gap between the bank layer 115 and the deposition mask, a spacer 116 (e.g., made of an organic material) can be disposed on the bank layer 115. As an example, the bank layer 115 and the spacer 116 can be made of the same material at the same time, or can be made of different materials. As an example, the spacer 116 can be omitted depending on the design.

The light emitting part 132 is disposed between the anode 131 and the cathode 133. The light emitting part 132 can serve to emit light and include at least one of a hole injection layer (HIL), a hole transport layer (HTL), a light emitting layer, an electron transport layer (ETL), and an electron injection layer (EIL). Here, the light emitting layer can be an organic light emitting layer, without being limited thereto.

The cathode 133 is disposed on the light emitting part 132 to serve to supply electrons to the light emitting part 132. The cathode 133 can be made of a conductive material. As an example, the cathode 133 can be made of a metallic material such as magnesium (Mg) or silver-magnesium (Ag:Mg), which is a conductive material with a low work function, but is not limited thereto.

When the display apparatus 100 is a top-emission type, the cathode 133 can be made of a transparent conductive oxide of the indium tin oxide (ITO), indium zinc oxide (IZO), indium tin zinc oxide (ITZO), zinc oxide (ZnO), and tin oxide (TiO) series.

An encapsulation part 117 can be disposed on the light emitting element 130 to reduce or prevent the thin film transistor 120 and the light emitting element 130 from being oxidized or damaged by moisture, oxygen, or impurities introduced from the outside.

The encapsulation part 117 can be made of an inorganic insulating material, an organic insulating material, or a stacked structure thereof.

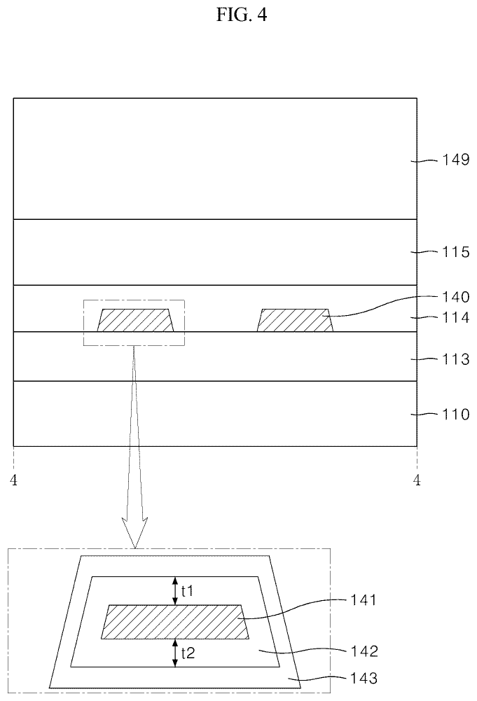

FIG. 4 is a cross-sectional view along line 4-4 in FIG. 2.

Referring to FIG. 4, the first planarization layer 113 can be disposed on the substrate 110 in the bending area BA. Signal lines 140 can be disposed on the first planarization layer 113, and the second planarization layer 114 can be disposed on the signal lines 140. The bank layer 115 can be disposed on the second planarization layer 114. Embodiments are not limited thereto. As an example, the signal lines 140 can be disposed on a layer other than the first planarization layer 113 (e.g., on the substrate 110, the buffer layer, the second planarization layer 114 or the bank layer 115). As an example, the signal lines 140 can be disposed on the same layer or on different layers.

A micro coating layer 149 can be disposed on the bank layer 115. Since stress acts on the signal lines 140 disposed on the substrate 110 to cause fine cracks in the signal lines 140 when the bending area BA of the substrate 110 is bent, the signal lines 140 can be protected by coating the bending area BA with the micro coating layer 149 to a predetermined thickness. The micro coating layer 149 can raise a position of a neutral plane of the bending area BA to reduce the stress applied to the signal lines 140. As an example, the micro coating layer 149 can be omitted depending on the design.

In one example, the bank layer 115 can be omitted from the bending area BA, and in this case, the micro coating layer 149 can be formed on the second planarization layer 114.

The signal lines 140 are disposed in a single layer on the first planarization layer 113, but are not limited thereto. In one example, the signal lines 140 can be disposed in a single layer on the second planarization layer 114. In another example, the signal lines 140 can be disposed in multiple layers. The signal lines 140 can be disposed not only on the first planarization layer 113 but also on the second planarization layer 114.

As an example, the signal line 140 can include a first layer 141, a second layer 142 surrounding an upper surface, side surfaces, and lower surface of the first layer 141, and a third layer 143 surrounding an upper surface, side surfaces, and lower surface of the second layer 142. The first layer 141 can be a core layer, the second layer 142 can be a first shell layer, and the third layer 143 can be a second shell layer. Although it is illustrated that there are two shell layers, embodiments are not limited thereto. As an example, there could be on shell layer or three or more shell layers.

The ionization tendency of the third layer 143 can be smaller than the ionization tendency of the second layer 142. The ionization tendency of the second layer 142 can be smaller than the ionization tendency of the first layer 141. The first layer 141 can have the greatest ionization tendency among the first layer 141, the second layer 142, and the third layer 143. Embodiments are not limited thereto.

As an example, the electrical conductivity of the third layer 143 can be smaller than the electrical conductivity of the second layer 142, and the electrical conductivity of the second layer 142 can be greater than the electrical conductivity of the first layer 141, without being limited thereto. As an example, the electrical conductivity of the first layer 141 can be greater than the electrical conductivity of the third layer 143, without being limited thereto. As an example, the second layer 142 can have the greatest electrical conductivity among the first layer 141, the second layer 142, and the third layer 143, without being limited thereto. Embodiments are not limited thereto. As an example, the first layer 141, the second layer 142, and the third layer 143 can have the same electrical conductivity or can have different conductivity in various ways.

For example, the first layer 141 can be made of magnesium (Mg), the second layer 142 can be made of aluminum (Al), and the third layer 143 can be made of titanium (Ti), without being limited thereto. As an example, the first layer 141, the second layer 142, and the third layer 143 can be made of the same conductive material or different conductive materials, such as a metal material, a conductive oxide material, without being limited thereto.

The stress applied to the bending area BA of the substrate 110 can cause micro cracks in the signal lines 140 positioned in the bending area BA, and materials that are not removed during the manufacturing process of the display apparatus 100, for example, tetramethylammonium hydroxide (TMAH) or tetramethylammonium (TMA) ions, can remain near the signal lines 140.

External moisture and residual materials can be introduced through the micro cracks of the signal lines, causing the corrosion of the lines, and eventually causing large cracks in the signal lines or a disconnection of the signal lines.

For example, during operation of the display apparatus, residual ions by an electric field generated in the signal lines can be concentrated on specific signal lines positioned in the bending area of the flexible substrate, eventually causing a disconnection of the specific signal lines. Since signals may not be transmitted through the disconnected signal lines, problems can occur in the operation of the display area, etc. and image quality can be significantly lowered.

In the first embodiment of the present disclosure, as described above, the signal line 140 can include the first layer 141, the second layer 142 surrounding the upper surface, side surfaces, and lower surface of the first layer 141, and the third layer 143 surrounding the upper surface, side surfaces, and lower surface of the second layer 142 and can be designed so that the ionization tendency of the third layer 143 is smaller than the ionization tendency of the second layer 142 and the ionization tendency of the second layer 142 is smaller than the ionization tendency of the first layer 141, thereby delaying or preventing the disconnection of the signal line 140.

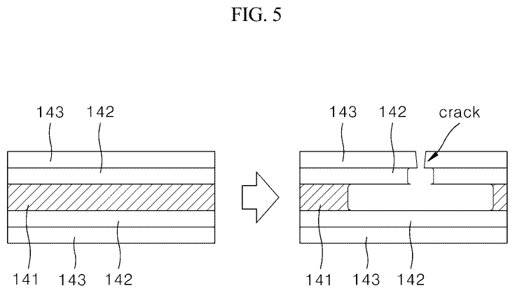

The principle that the disconnection of the signal line 140 is delayed or prevented will be described with reference to FIG. 5.

FIG. 5 shows a corrosion process of a signal line according to the first embodiment of the present disclosure.

Referring to FIG. 5, when the substrate 101 is bent, a tensile force is applied to the signal lines 140 disposed in the bending area BA, and thus micro cracks are mainly formed in the third layer 143 positioned in an upper part of the signal lines 140, without being limited thereto.

When micro cracks are formed in the third layer 143 of the signal line 140, as external moisture and residual materials are introduced through the micro cracks, a portion of the second layer 142 having a greater ionization tendency than the third layer 143 preferentially is corroded. When the portion of the second layer 142 is corroded and the first layer 141 is exposed, the first layer 141 having a greater ionization tendency than the second layer 142 is corroded prior to the second layer 142. As the first layer 141 is corroded, voids are formed in the second layer 142, and external moisture and residual materials can be guided along the voids by a capillary phenomenon, and the corrosion of the first layer 141 can occur effectively. As an example, space communicating with the crack and the void and greater than the crack and the void can be formed in the first layer 141, without being limited thereto. Therefore, it is possible to delay or prevent the corrosion of the second layer 142 that serves as the main signal transmission medium. Therefore, it is possible to delay or prevent the disconnection of the signal line 140.

Referring back to FIG. 4, as an example, a thickness t1 of the second layer 142 adjacent to the upper surface of the first layer 141 can be smaller than a thickness t2 of the second layer 142 adjacent to the lower surface of the first layer 141. Embodiments are not limited thereto. As an example, the thickness t1 of the second layer 142 adjacent to the upper surface of the first layer 141 can be the same as or greater than a thickness t2 of the second layer 142 adjacent to the lower surface of the first layer 141. As an example, the second layer 142 can have a constant thickness or a varied thickness along the circumferential direction.

When the substrate 101 is bent, a tensile force is applied to the signal lines 140 disposed in the bending area BA, and thus micro cracks are mainly formed in the third layer 143 positioned in the upper part of the signal lines 140. For this reason, the corrosion of the second layer 142 adjacent to the upper surface of the first layer 141 occurs first.

By designing the thickness of the second layer 142 adjacent to the upper surface of the first layer 141 to be relatively small, the first layer 141 having a greater ionization tendency than the second layer 142 can be exposed at the beginning of the corrosion process, thereby efficiently delaying or preventing the additional corrosion of the second layer 142 that serves as the main signal transmission medium.

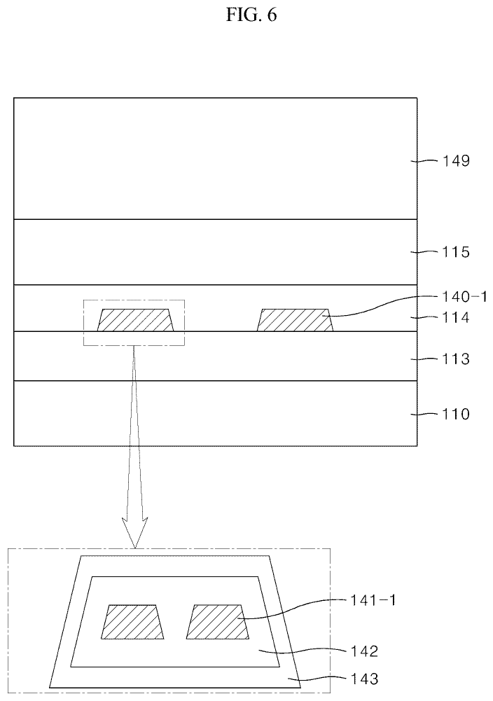

FIG. 6 is a cross-sectional view of a bending area according to a second embodiment of the present disclosure.

Referring to FIG. 6, the first planarization layer 113 can be disposed on the substrate 110 in the bending area BA. Signal lines 140-1 can be disposed on the first planarization layer 113, and the second planarization layer 114 can be disposed on the signal lines 140-1. The bank layer 115 can be disposed on the second planarization layer 114. The micro coating layer 149 can be disposed on the bank layer 115. In one example, the bank layer 115 can be omitted.

The signal line 140-1 can include a first layer 141-1, the second layer 142 surrounding an upper surface, side surfaces, and lower surface of the first layer 141-1, and the third layer 143 surrounding the upper surface, side surfaces, and lower surface of the second layer 142. The first layer 141-1 can be a core layer, the second layer 142 can be a first shell layer, and the third layer 143 can be a second shell layer. Although FIG. 6 shows two first layers 140-1, the present disclosure is not limited thereto. As an example, there could be three or more first layers 140-1. As an example, the second layer 142 surrounds an upper surface, side surfaces, and lower surface of each of the first layers 141-1. As an example, the second layer 142 fills a space between the first layers 141-1.

The ionization tendency of the third layer 143 can be smaller than the ionization tendency of the second layer 142, and the ionization tendency of the second layer 142 can be smaller than the ionization tendency of the first layer 141-1. The first layer 141-1 can have the greatest ionization tendency among the first layer 141-1, the second layer 142, and the third layer 143, without being limited thereto.

The electrical conductivity of the third layer 143 can be smaller than the electrical conductivity of the second layer 142, and the electrical conductivity of the second layer 142 can be greater than the electrical conductivity of the first layer 141-1. The electrical conductivity of the first layer 141-1 can be greater than the electrical conductivity of the third layer 143. The second layer 142 can have the greatest electrical conductivity among the first layer 141-1, the second layer 142, and the third layer 143, without being limited thereto.

For example, the first layer 141-1 can be made of magnesium (Mg), the second layer 142 can be made of aluminum (Al), and the third layer 143 can be made of titanium (Ti), without being limited thereto.

In the second embodiment of the present disclosure, as described above, the signal line 140-1 can include a plurality of first layers 141-1, the second layer 142 surrounding upper surfaces, side surfaces, and lower surfaces of the plurality of first layers 141-1, and the third layer 143 surrounding the upper surface, side surfaces, and lower surface of the second layer 142 and can be designed so that the ionization tendency of the third layer 143 is smaller than the ionization tendency of the second layer 142 and the ionization tendency of the second layer 142 is smaller than the ionization tendency of the first layer 141-1, thereby delaying or preventing the disconnection of the signal line 140-1.

By configuring the plurality of first layers 141-1, the void formed in the second layer 142 due to the corrosion of the first layer 141-1 becomes narrower, and external moisture and residual materials can be more deeply guided into the void by a capillary phenomenon. Therefore, the corrosion of the first layer 141-1 can occur more effectively, and the corrosion of the second layer 142 can be efficiently delayed or prevented.

As described with reference to FIG. 4, as an example, the thickness of the second layer 142 adjacent to the upper surface of the first layer 141-1 can be smaller than the thickness of the second layer 142 adjacent to the lower surface of the first layer 141-1.

By designing the thickness of the second layer 142 adjacent to the upper surface of the first layer 141-1 to be relatively small, the first layer 141-1 having a greater ionization tendency than the second layer 142 can be exposed at the beginning of the corrosion process, thereby efficiently delaying or preventing the additional corrosion of the second layer 142 that serves as the main signal transmission medium.

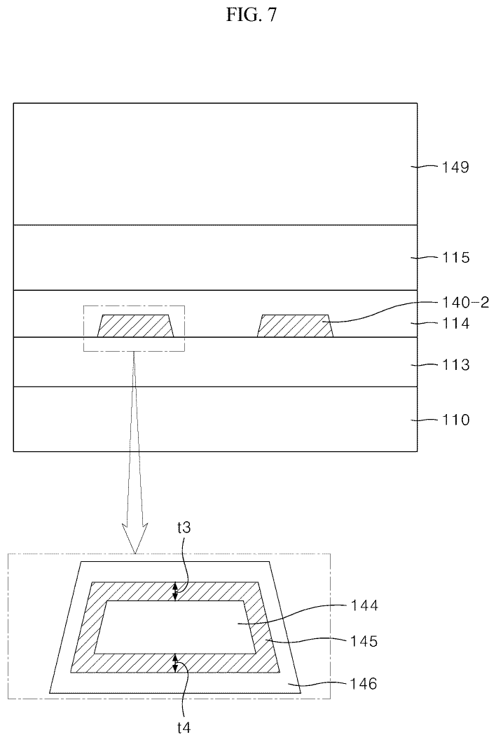

FIG. 7 is a cross-sectional view according to a third embodiment of the present disclosure.

Referring to FIG. 7, the first planarization layer 113 can be disposed on the substrate 110 in the bending area BA. Signal lines 140-2 can be disposed on the first planarization layer 113, and the second planarization layer 114 can be disposed on the signal lines 140-2. The bank layer 115 can be disposed on the second planarization layer 114. The micro coating layer 149 can be disposed on the bank layer 115. In one example, the bank layer 115 can be omitted.

The signal line 140-2 can include a first layer 144, a second layer 145 surrounding an upper surface, side surfaces, and lower surface of the first layer 144, and a third layer 146 surrounding an upper surface, side surfaces, and lower surface of the second layer 145. The first layer 144 can be a core layer, the second layer 145 can be a first shell layer, and the third layer 146 can be a second shell layer.

The ionization tendency of the third layer 146 can be smaller than the ionization tendency of the second layer 145, and the ionization tendency of the second layer 145 can be greater than the ionization tendency of the first layer 144. The second layer 145 can have the greatest ionization tendency among the first layer 144, the second layer 145, and the third layer 146, without being limited thereto.

The electrical conductivity of the third layer 146 can be smaller than the electrical conductivity of the second layer 145, and the electrical conductivity of the second layer 145 can be smaller than the electrical conductivity of the first layer 144. The first layer 144 can have the greatest electrical conductivity among the first layer 144, the second layer 145, and the third layer 146, without being limited thereto.

For example, the first layer 144 can be made of aluminum (Al), the second layer 145 can be made of magnesium (Mg), and the third layer 146 can be made of titanium (Ti).

In the third embodiment of the present disclosure, as described above, the signal line 140-2 can include the first layer 144, the second layer 145 surrounding the upper surface, side surfaces, and lower surface of the first layer 144, and the third layer 146 surrounding the upper surface, side surfaces, and lower surface of the second layer 145 and can be designed so that the ionization tendency of the third layer 146 is smaller than the ionization tendency of the second layer 145 and the ionization tendency of the second layer 145 is greater than the ionization tendency of the first layer 144, thereby delaying or preventing the disconnection of the signal line 140-2.

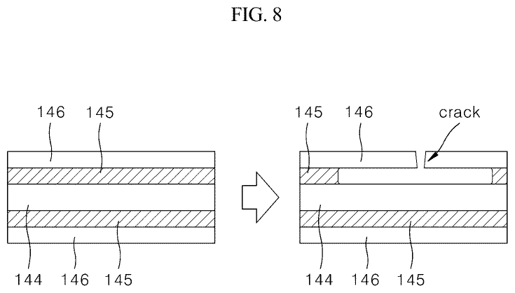

The principle that the disconnection of the signal line 140-2 is delayed or prevented will be described with reference to FIG. 8.

FIG. 8 shows a corrosion process of a signal line according to the third embodiment of the present disclosure.

Referring to FIG. 8, when micro cracks are formed in the third layer 146 of the signal line 140-2, as external moisture and residual materials are introduced through the micro cracks, a portion of the second layer 145 having a greater ionization tendency than the third layer 146 preferentially is corroded. When the portion of the second layer 145 is corroded and the first layer 144 is exposed, the second layer 145 having a smaller ionization tendency than the first layer 144 is corroded prior to the first layer 144. As the second layer 145 is corroded, voids are formed and external moisture and residual materials can be guided along the voids by a capillary phenomenon, and the corrosion of the second layer 145 can occur continuously. Therefore, it is possible to delay or prevent the corrosion of the first layer 144 that serves as the main signal transmission medium. Therefore, it is possible to delay or prevent the disconnection of the signal line 140-2.

Referring back to FIG. 7, as an example, the thickness of the second layer 145 adjacent to the upper surface of the first layer 144 can be larger than the thickness of the second layer 145 adjacent to the lower surface of the first layer 144, without being limited thereto.

Since the ionization tendency of the second layer 145 is greater, the thickness of the second layer 145 adjacent to the upper surface of the first layer 144 can be designed to be relatively large to delay the exposure of the first layer 144, and the corrosion of the first layer 144 that serves as the main signal conductor can be effectively delayed or prevented.

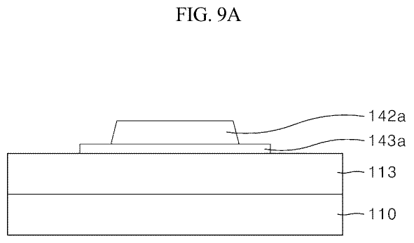

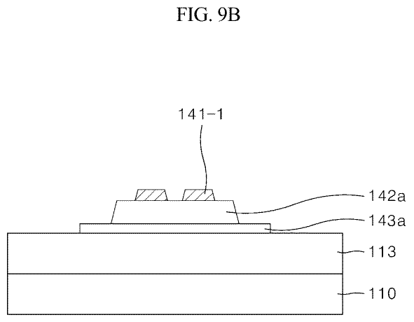

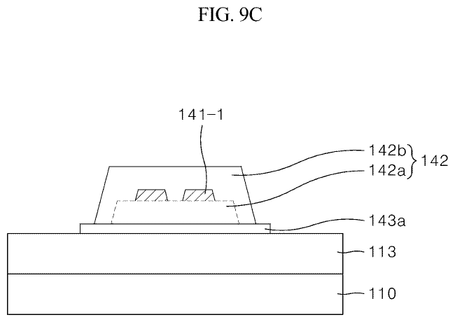

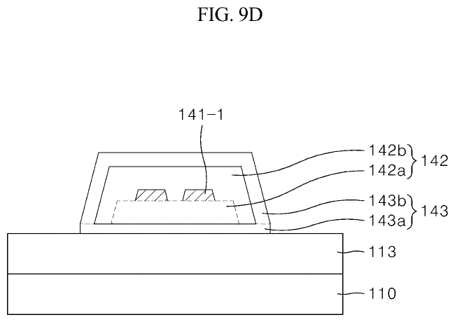

FIGS. 9A to 9D show a manufacturing method of the signal line 140-1 according to the second embodiment of the present disclosure.

Referring to FIG. 9A, after the first planarization layer 113 is formed on the substrate 110, a third lower layer 143a can be formed in an area in which the signal line 140-1 is formed on the first planarization layer 113.

A second lower layer 142a can be formed on the third lower layer 143a. The ionization tendency of the second lower layer 142a can be greater than the ionization tendency of the third lower layer 143a. The electrical conductivity of the second lower layer 142a can be greater than the electrical conductivity of the third lower layer 143a. For example, the third lower layer 143a can be made of titanium, and the second lower layer 142a can be made of aluminum.

Referring to FIG. 9B, a plurality of first layers 141-1 spaced apart from each other can be formed on the second lower layer 142a. The ionization tendency of the first layer 141-1 can be greater than the ionization tendency of the second lower layer 142a. The electrical conductivity of the first layer 141-1 can be smaller than the electrical conductivity of the second lower layer 142a. For example, the first layer 141-1 can be made of magnesium.

Referring to FIG. 9C, a second upper layer 142b covering the second lower layer 142a and the plurality of first layers 141-1 can be formed on the third lower layer 143a. The second upper layer 142b can cover the side surfaces and upper surfaces of the plurality of first layers 141-1. As an example, the second upper layer 142b can expose a side surface of the third lower layer 143a. As an example, the second upper layer 142b can expose an end portion of the third lower layer 143a. As an example, the second upper layer 142b can expose an upper surface and a top surface of the end portion of the third lower layer 143a.

As an example, the second upper layer 142b can have the same or similar ionization tendency and electrical conductivity as the second lower layer 142a, or can have a different ionization tendency and electrical conductivity from the second lower layer 142a. As an example, the second upper layer 142b can be made of the same material as or a different material from the second lower layer 142a. As an example, the second upper layer 142b can have the same thickness as or a different thickness from the second lower layer 142a.

The second upper layer 142b and the second lower layer 142a can form the second layer 142 surrounding the lower surfaces, side surfaces, and upper surfaces of the plurality of first layers 141-1.

Referring to FIG. 9D, a third upper layer 143b can be formed on the third lower layer 143a covering the second upper layer 142b. The third upper layer 143b can have the same or similar ionization tendency and electrical conductivity as or a different ionization tendency and electrical conductivity from the third lower layer 143a. As an example, the third upper layer 143b can contact a side surface of the third lower layer 143a exposed by the second upper layer 142b. As an example, the third upper layer 143b can contact a top surface and a side surface of an end portion of the third lower layer 143a exposed by the second upper layer 142b. As an example, the third upper layer 143b can be made of the same material as or a different material from the third lower layer 143a.

The third upper layer 143b and the third lower layer 143a can form the third layer 143 surrounding the lower surface, side surfaces, and upper surface of the second layer 142.

Therefore, the signal line 140-1 including the plurality of first layers 141-1, the second layer 142 surrounding the upper surfaces, side surfaces, and lower surfaces of the first layers 141-1, and the third layer 143 surrounding the upper surface, side surfaces, and lower surfaces of the second layer 142 can be formed.

The manufacturing method of the signal line 140 according to the first embodiment is the same as the manufacturing method of the signal line 140-1 described with reference to FIGS. 9A to 9D except for forming one first layer.

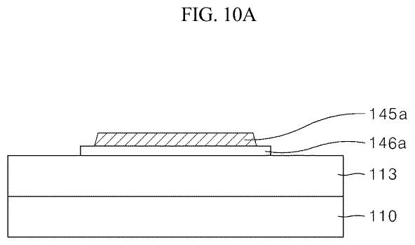

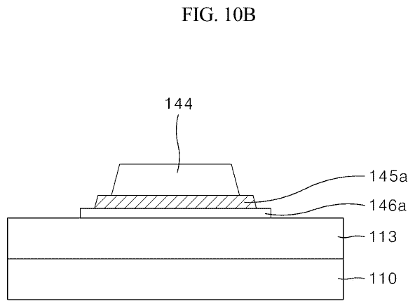

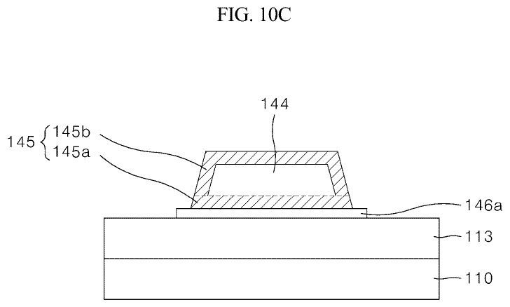

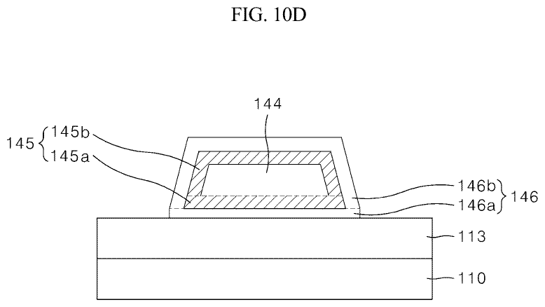

FIGS. 10A to 10D show a manufacturing method of the signal line 140-2 according to the third embodiment of the present disclosure.

Referring to FIG. 10A, after the first planarization layer 113 is formed on the substrate 110, the third lower layer 146a can be formed in an area in which the signal line 140-2 is formed on the first planarization layer 113.

In addition, the second lower layer 145a can be formed on the third lower layer 146a. The ionization tendency of the second lower layer 145a can be greater than the ionization tendency of the third lower layer 146a. The electrical conductivity of the second lower layer 145a can be greater than the electrical conductivity of the third lower layer 146a. For example, the third lower layer 146a can be made of titanium, and the second lower layer 145a can be made of magnesium.

Referring to FIG. 10B, the first layer 144 can be formed on the second lower layer 145a. The ionization tendency of the first layer 144 can be smaller than the ionization tendency of the second lower layer 145a. The electrical conductivity of the first layer 144 can be greater than the electrical conductivity of the second lower layer 145a. For example, the first layer 144 can be made of aluminum.

Referring to FIG. 10C, the second upper layer 145b covering the second lower layer 145a and the first layer 144 can be formed on the third lower layer 146a. The second upper layer 145b can cover the side surfaces and upper surface of the first layer 144.

The second upper layer 145b can have the same or similar ionization tendency and electrical conductivity as the second lower layer 145a, without being limited thereto.

The second upper layer 145b and the second lower layer 145a can form the second layer 145 surrounding the lower surface, side surfaces, and upper surface of the first layer 144.

Referring to FIG. 10D, the third upper layer 146b covering the second upper layer 145b can be formed on the third lower layer 146a. The third upper layer 146b can have the same or similar ionization tendency and electrical conductivity as the third lower layer 146a.

The third upper layer 146b and the third lower layer 146a can form the third layer 146 surrounding the lower surface, side surfaces, and upper surface of the second layer 145.

Therefore, the signal line 140-2 including the first layer 144, the second layer 145 surrounding the upper surface, side surfaces, and lower surface of the first layer 144, and the third layer 146 surrounding the upper surface, side surfaces, and lower surface of the second layer 145 can be formed.

The display apparatus according to the embodiments of the present disclosure can be described as follows.

A display apparatus according to embodiments of the present disclosures includes a substrate including a display area having a plurality of sub-pixels and a non-display area surrounding the display area and having a bending area, and at least one signal line disposed in the bending area on the substrate, wherein the at least one signal line includes at least one first layer, a second layer surrounding an upper surface, side surfaces, and lower surface of the at least one first layer, and a third layer surrounding an upper surface, side surfaces, and lower surface of the second layer.

According to one or more embodiments of the present disclosure, the ionization tendency of the third layer can be smaller than the ionization tendency of the second layer, and the ionization tendency of the second layer can be smaller than the ionization tendency of the first layer. In this case, a thickness of the second layer adjacent to the upper surface of the first layer can be smaller than a thickness of the second layer adjacent to the lower surface of the first layer.

According to one or more embodiments of the present disclosure, the at least one first layer can include a plurality of first layers spaced apart from each other.

According to one or more embodiments of the present disclosure, the electrical conductivity of the third layer can be smaller than the electrical conductivity of the second layer, and the electrical conductivity of the second layer can be greater than the electrical conductivity of the first layer.

According to one or more embodiments of the present disclosure, the first layer can be made of magnesium (Mg), the second layer can be made of aluminum (Al), and the third layer can be made of titanium (Ti).

According to one or more embodiments of the present disclosure, the ionization tendency of the third layer can be smaller than the ionization tendency of the second layer, and the ionization tendency of the second layer can be greater than the ionization tendency of the first layer. In this case, a thickness of the second layer adjacent to the upper surface of the first layer can be larger than a thickness of the second layer adjacent to the lower surface of the first layer.

According to one or more embodiments of the present disclosure, the electrical conductivity of the third layer can be smaller than the electrical conductivity of the second layer, and the electrical conductivity of the second layer can be greater than the electrical conductivity of the first layer.

According to one or more embodiments of the present disclosure, the first layer can be made of aluminum (Al), the second layer can be made of magnesium (Mg), and the third layer can be made of titanium (Ti).

A display apparatus according to embodiments of the present disclosure can include a substrate including a display area having a plurality of sub-pixels and a non-display area disposed near the display area, and at least one signal line disposed in the non-display area on the substrate, wherein the at least one signal line can include at least one core layer, a first shell layer surrounding an upper surface, side surfaces, and lower surface of the at least one core layer, and a second shell layer surrounding an upper surface, side surfaces, and lower surface of the first shell layer.

According to one or more embodiments of the present disclosure, the ionization tendency of the core layer among the core layer, the first shell layer, and the second shell layer can be the smallest. In this case, the thickness of the first shell layer adjacent to the upper surface of the core layer can be smaller than the thickness of the first shell layer adjacent to the lower surface of the core layer.

According to one or more embodiments of the present disclosure, the at least one core layer can include a plurality of core layers spaced apart from each other.

According to one or more embodiments of the present disclosure, the electrical conductivity of the core layer can be smaller than the electrical conductivity of the first shell layer and greater than the electrical conductivity of the second shell layer.

According to one or more embodiments of the present disclosure, the core layer can be made of magnesium (Mg), the first shell layer can be made of aluminum (Al), and the second shell layer can be made of titanium (Ti).

According to one or more embodiments of the present disclosure, the ionization tendency of the first shell layer among the core layer, the first shell layer, and the second shell layer can be the smallest.

According to one or more embodiments of the present disclosure, the thickness of the first shell layer adjacent to the upper surface of the core layer can be larger than the thickness of the first shell layer adjacent to the lower surface of the core layer.

According to one or more embodiments of the present disclosure, the electrical conductivity of the first shell layer can be smaller than the electrical conductivity of the core layer and larger than the electrical conductivity of the second shell layer.

According to one or more embodiments of the present disclosure, the core layer can be made of aluminum (Al), the first shell layer can be made of magnesium (Mg), and the second shell layer can be made of titanium (Ti).

According to the embodiments of the present disclosure, by making the signal lines have a multi-core-shell structure including metal materials with different ionization tendencies, it is possible to delay or prevent the cracking and disconnection of the signal lines disposed in the bending area of the substrate of the display apparatus.

According to the embodiments of the present disclosure, it is possible to improve the reliability and lifetime of the display apparatus. Therefore, it is possible to reduce greenhouse gases generated due to the manufacturing process for producing a new display apparatus to replace a display apparatus with a reliability failure or an end-of-life display apparatus.

The effects of the present disclosure are not limited to the above-described effects, and other effects that are not mentioned will be able to be clearly understood by those skilled in the art from the following description.

Although the embodiments of the present disclosure have been described in detail with reference to the accompanying drawings, the present disclosure is not necessarily limited to these embodiments, and various modifications can be carried out without departing from the technical spirit of the present disclosure. Therefore, the embodiments disclosed in the present disclosure are not intended to limit the technical spirit of the present disclosure, but is intended to describe the same, and the scope of the technical spirit of the present disclosure is not limited by these embodiments.

What is claimed is:

1. A display apparatus comprising:
a substrate including a display area having a plurality of sub-pixels and a non-display area adjacent to the display area, the non-display area having a bending area; and
at least one signal line disposed in the bending area on the substrate,
wherein the at least one signal line includes at least one first layer, a second layer surrounding an upper surface, side surfaces, and a lower surface of the at least one first layer, and a third layer surrounding an upper surface, side surfaces, and a lower surface of the second layer.

2. The display apparatus of claim 1, wherein an ionization tendency of the third layer is smaller than an ionization tendency of the second layer, and the ionization tendency of the second layer is smaller than an ionization tendency of the first layer.

3. The display apparatus of claim 2, wherein a thickness of the second layer adjacent to an upper surface of the first layer is smaller than a thickness of the second layer adjacent to a lower surface of the first layer.

4. The display apparatus of claim 1, wherein the at least one first layer includes a plurality of first layers spaced apart from each other.

5. The display apparatus of claim 4, wherein the second layer surrounds an upper surface, side surfaces, and a lower surface of each of the plurality of first layers.

6. The display apparatus of claim 1, wherein an electrical conductivity of the third layer is smaller than an electrical conductivity of the second layer, and the electrical conductivity of the second layer is greater than an electrical conductivity of the first layer.

7. The display apparatus of claim 1, wherein the first layer includes magnesium, the second layer includes aluminum, and the third layer includes titanium.

8. The display apparatus of claim 1, wherein an ionization tendency of the third layer is smaller than an ionization tendency of the second layer, and the ionization tendency of the second layer is greater than an ionization tendency of the first layer.

9. The display apparatus of claim 8, wherein a thickness of the second layer adjacent to an upper surface of the first layer is larger than a thickness of the second layer adjacent to a lower surface of the first layer.

10. The display apparatus of claim 1, wherein an electrical conductivity of the third layer is smaller than an electrical conductivity of the second layer, and the electrical conductivity of the second layer is smaller than an electrical conductivity of the first layer.

11. The display apparatus of claim 1, wherein the first layer includes aluminum, the second layer includes magnesium, and the third layer includes titanium.

12. The display apparatus of claim 1, wherein an ionization tendency of the second layer is different from an ionization tendency of the first layer, and an ionization tendency of the third layer is smaller than the ionization tendency of the second layer.

13. The display apparatus of claim 1, wherein a crack is formed in the third layer, a void greater than the crack is formed in the second layer, and a space communicating with the crack and the void and greater than the void is formed in the first layer.

14. The display apparatus of claim 13, wherein the crack and the void are formed above the space.

15. The display apparatus of claim 1, wherein a crack is formed in the third layer, and a space communicating with the crack is formed in the second layer.

16. The display apparatus of claim 1, wherein the at least one signal line extends from the display area to at least one pad positioned in the non-display area by passing through the bending area.

17. A display apparatus comprising:
a substrate including a display area having a plurality of sub-pixels and a non-display area disposed adjacent to the display area; and
at least one signal line disposed in the non-display area on the substrate,
wherein the at least one signal line includes at least one core layer, a first shell layer surrounding an upper surface, side surfaces, and a lower surface of the at least one core layer, and a second shell layer surrounding an upper surface, side surfaces, and a lower surface of the first shell layer.

18. The display apparatus of claim 17, wherein an ionization tendency of the at least one core layer is the smallest among the at least one core layer, the first shell layer, and the second shell layer.

19. The display apparatus of claim 18, wherein a thickness of the first shell layer adjacent to an upper surface of the at least one core layer is smaller than a thickness of the first shell layer adjacent to a lower surface of the at least one core layer.

20. The display apparatus of claim 17, wherein the at least one core layer includes a plurality of core layers spaced apart from each other.

21. The display apparatus of claim 17, wherein an electrical conductivity of the at least one core layer is smaller than the electrical conductivity of the first shell layer and is greater than the electrical conductivity of the second shell layer.

22. The display apparatus of claim 17, wherein the at least one core layer includes magnesium, the first shell layer includes aluminum, and the second shell layer includes titanium.

23. The display apparatus of claim 17, wherein an ionization tendency of the first shell layer is the smallest among the at least one core layer, the first shell layer, and the second shell layer.

24. The display apparatus of claim 23, wherein a thickness of the first shell layer adjacent to an upper surface of the at least one core layer is larger than a thickness of the first shell layer adjacent to a lower surface of the at least one core layer.

25. The display apparatus of claim 17, wherein an electrical conductivity of the first shell layer is smaller than an electrical conductivity of the at least one core layer and is greater than an electrical conductivity of the second shell layer.

26. The display apparatus of claim 17, wherein the at least one core layer includes aluminum, the first shell layer includes magnesium, and the second shell layer includes titanium.

27. The display apparatus of claim 17, further comprising a micro coating layer disposed over the substrate to overlap the at least one signal line disposed in the non-display area.

28. A display apparatus comprising:
a substrate including a display area having a plurality of sub-pixels and a non-display area adjacent to the display area; and
at least one signal line disposed in the non-display area on the substrate,
wherein the at least one signal line includes at least one first layer, a second layer surrounding an upper surface, side surfaces, and a lower surface of the at least one first layer, and a third layer surrounding an upper surface, side surfaces, and a lower surface of the second layer, and
wherein a crack is formed in the third layer, and a space greater than the crack and communicating with the crack is formed in only one of the at least one first layer and the second layer.

29. The display apparatus of claim 28, wherein the non-display area has a bending area through which the at least one signal line passes, and
wherein the crack is formed in the bending area.
